(19) United States
(12) Patent Application Publication
(10) Pub. No.: US 2026/0341636 A1
(43) Pub. Date: Oct. 29, 2026

(54) INDUCTIVELY COUPLED PLASMA SOURCE WITH PARALLEL HELICAL RF COILS

(71) Applicant: LAM RESEARCH CORPORATION, Fremont, CA (US)

(72) Inventors: Wei Yi LUO, Fremont, CA (US); Himanshu CHOKSHI, Fremont, CA (US); Norman MERTKE, San Jose, CA (US); Abhinav PRAKASH, Santa Clara, CA (US)

(21) Appl. No.: 19/140,273

(22) PCT Filed: Dec. 15, 2023
(86) PCT No.: PCT/US2023/084205

§ 371 Date: Jun. 17, 2025

Related U.S. Application Data
(60) Provisional application No. 63/434,305, filed on Dec. 21, 2022.

(51) Int. Cl. H01J 37/32

(52) U.S. Cl. CPC H01J 37/3211; H01J 37/32183; H01J 2237/3343

(57) ABSTRACT

A substrate processing system includes a processing chamber and an RF generator configured to generate RF power. A matching network connected to the RF generator. N helical coils are connected to the matching network and include M turns, where N and M are integers greater than one. The N helical coils are interwound symmetrically around an outer surface of the processing chamber. The N helical coils are connected in parallel to the matching network.

### CROSS-REFERENCE TO RELATED APPLICATIONS

This application claims the benefit of U.S. Provisional Application No. 63/434,305, filed on Dec. 21, 2022. The entire disclosure of the application referenced above is incorporated herein by reference.

### FIELD

The present disclosure relates to substrate processing systems, and more particularly to an inductively coupled plasma source with parallel helical radio frequency (RF) coils.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to etch film on a substrate such as a semiconductor wafer. The substrate processing systems typically include a processing chamber, a gas distribution device, and a substrate support. During processing, the substrate is arranged on the substrate support. Different gas mixtures may be introduced into the processing chamber and radio frequency (RF) plasma may be used to activate chemical reactions.

In some substrate processing systems, plasma is generated inside of the processing chamber using inductive coils arranged outside of the processing chamber. Current flowing through the inductive coils generates a time varying electromagnetic field inside of the processing chamber. The time varying electromagnetic field generates plasma by exciting a process gas mixture in the processing chamber. The plasma is used to treat substrates arranged on the substrate support. Process non-uniformity may be caused by variations in the plasma at different locations in the processing chamber.

### SUMMARY

A substrate processing system includes a processing chamber and an RF generator configured to generate RF power. A matching network is connected to the RF generator. N helical coils are connected to the matching network and include M turns, where N and M are integers greater than one. The N helical coils are interwound symmetrically around an outer surface of the processing chamber. The N helical coils are connected in parallel to the matching network.

In other features, N and M are equal to two, N is equal to 3, or N is equal to 4. First ends of the N helical coils are connected to the matching network. The first ends of the N helical coils are connected adjacent to a bottom portion of the processing chamber. Second ends of the N helical coils are connected to a first terminal of a first capacitor.

In other features, the second ends of the N helical coils are connected adjacent to a top portion of the processing chamber. A ground plane is arranged between the first capacitor and the N helical coils. An enclosure surrounds the first capacitor, wherein the enclosure is made of a conducting material and is grounded. The N helical coils are rotationally offset by 360/N degrees.

In other features, N capacitors that are connected between middle portions of the N helical coils. N is equal to two, 3, or 4. An enclosure surrounds the first capacitor and the N capacitors. The enclosure is made of a conducting material and is grounded.

In other features, the processing chamber has one of a dome shape and a bell jar shape. The N helical coils are smoothly and gradually wound into a helical shape.

In other features, the N helical coils are wound into a helical shape with a plurality of levels and transitions between the plurality of levels. The plurality of levels is evenly spaced in a vertical direction. A first vertical spacing between a first pair of the plurality of levels is different than a second vertical spacing between a second pair of the plurality of levels.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example of a substrate processing system according to the present disclosure;

FIG. 1B is a perspective view of an example of an asymmetric serial RF source arranged around and outer surface of a processing chamber;

FIG. 1C is an electrical schematic of the asymmetric serial RF source of FIG. 1B;

FIG. 2A is a simplified cross-sectional view of an example of a symmetric parallel RF source arranged around and outer surface of a processing chamber according to the present disclosure;

FIG. 2B is an electrical schematic of the symmetric parallel RF source in FIG. 2A;

FIG. 2C is a perspective view of an example of first and second interwound helical coils according to the present disclosure;

FIG. 2D is a side view of the first and second interwound helical coils of FIG. 2C;

FIG. 2E is a perspective view of another example of first and second interwound helical coils according to the present disclosure;

FIG. 2F is a side view of the first and second interwound helical coils of FIG. 2C;

FIG. 3A is a simplified cross-sectional view of another example of a symmetric parallel RF source arranged around an outer surface of a processing chamber and including a middle capacitor on each helical coil according to the present disclosure;

FIG. 3B is an electrical schematic of the symmetric parallel RF source in FIG. 3A;

FIGS. 4A and 4B are electrical schematics of examples of symmetric parallel RF sources including three helical coils; and

FIGS. 5A and 5B are electrical schematics of example of a symmetric parallel RF source including four helical coils.

In the drawings, reference numbers may be reused to identify similar and/or identical elements.

### DETAILED DESCRIPTION

Substrate processing systems according to the present disclosure reduce plasma non-uniformity in the azimuthal direction using a symmetric parallel RF coil source.

When using an asymmetric series RF source, one end of a first or bottom coil is connected to a first terminal of a first capacitor. The first coil is wound around a bottom portion of a processing chamber and connected to a first terminal of the first capacitor (arranged adjacent to a middle of the processing chamber). The processing chamber may have a dome shape or a bell jar shape. A second terminal of the first capacitor is connected to one end of a second or top coil that is wound around an upper portion of the processing chamber. Another end of the second coil is connected a second capacitor located above the processing chamber.

The asymmetric series arrangement of coils causes asymmetric RF coupling to the plasma in the azimuthal direction. Since the first capacitor is located close to the processing chamber, the first capacitor causes localized low RF coupling to the plasma and creates a cold spot, which increases plasma non-uniformity and overall processing non-uniformity.

Substrate processing systems according to the present disclosure include a symmetric parallel helical RF coil source including two or more inductive coils. For example, first and second helical coils are arranged 180 degrees apart and interwound around the processing chamber and connected in parallel. Since each parallel helical coil has two turns only, it has lower inductance as compared to a four-turn coil of the series helical RF coil source. Therefore, the first capacitor (arranged adjacent to the outside of the processing chamber in the asymmetrical series arrangement) can be omitted without causing high RF voltages on the parallel coils. Avoiding high RF voltages on the RF coil prevents strong ion bombardment to the processing chamber, which may generate particles or cause chamber deposition issues. Thus, the parallel helical RF coil source removes the first capacitor close to the processing chamber and eliminates the cold spot non-uniformity issue produced by the asymmetric series RF source described above. As a result, the symmetric parallel RF source improves RF coupling uniformity and wafer etching uniformity in the azimuthal direction.

In other examples, if a high frequency such as 27.12 MHz or higher is used, or there is a need to further reduce the RF voltage on the parallel RF coils, the first and second helical coils are split at mid-portions thereof and connected to first and second capacitors, respectively. The first and second capacitors are connected to the split first and second helical coils on opposite sides of the processing chamber. All the capacitors are isolated and shielded by the grounded enclosure to avoid possible effect to the electromagnetic field around the processing chamber and to the plasma inside the processing chamber.

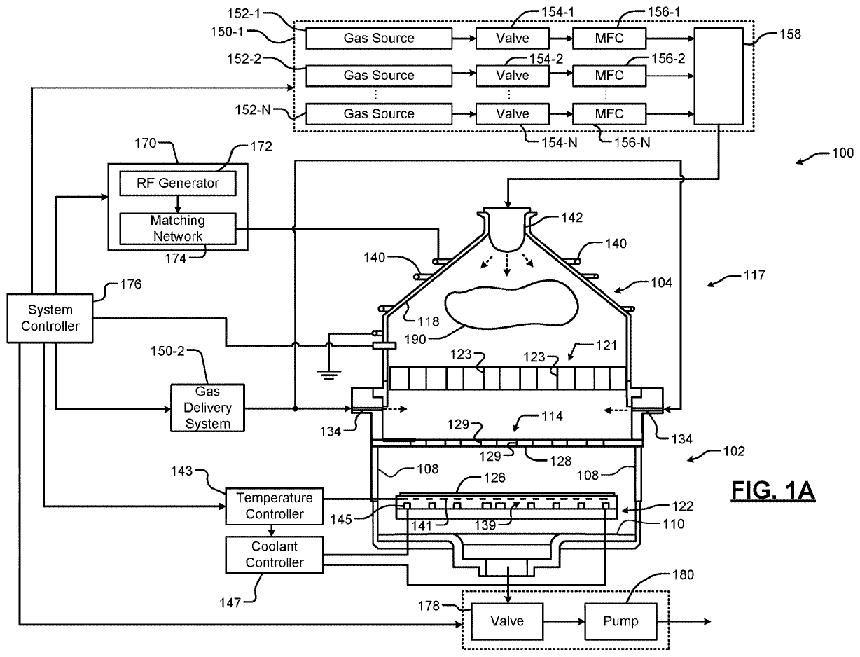

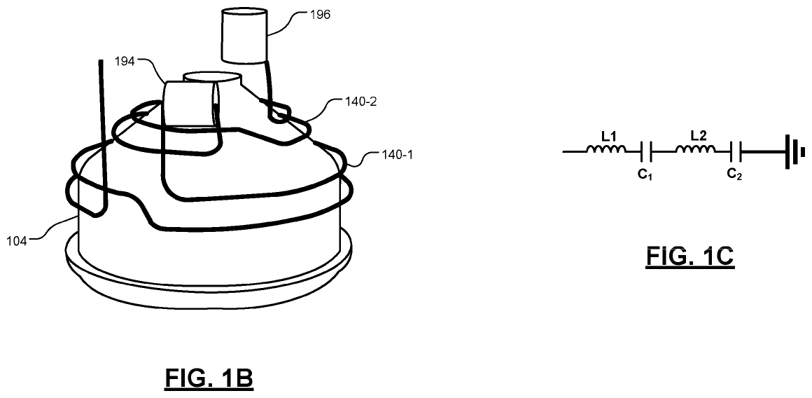

Referring now to FIG. 1A, an example of a substrate processing system 100 is shown. While a specific processing chamber is shown, the present disclosure also relates to other types of systems using inductively coupled plasma. The substrate processing system 100 includes a processing chamber 117 having a lower chamber 102 and an upper chamber 104. In some examples, the processing chamber 117 includes an inductively coupled plasma (ICP) source. In some examples, the upper chamber 104 has a bell jar shape, although other shapes can be used. The lower chamber 102 is defined by chamber sidewall surfaces 108, a chamber bottom surface 110 and a lower surface of a gas distribution device 114. In some examples, the gas distribution device 114 is omitted. The upper chamber 104 is defined by an upper surface of the gas distribution device 114 and an inner surface of an upper chamber wall 118 (for example a bell jar-shaped chamber).

The substrate processing system 100 further includes a gas distribution device 121 such as a platen or a plate. The gas distribution device 121 is used to filter ions generated by the plasma and to block VUV or UV radiation. The gas distribution device 121 is arranged between a substrate support 122 and the upper chamber 104. Secondary gas injectors 134 inject secondary gas in a location between the gas distribution device 121 and the substrate support 122. In some examples, the secondary gas injectors 134 are arranged at uniform intervals around the periphery of the processing chamber.

In some examples, the gas distribution device 121 includes a plurality of spaced through holes 123 for delivering process gas to the upper chamber 104, as will be described further below. The through holes 123 may be uniformly spaced around a periphery of the upper chamber 104. In some examples, the process gas is delivered by the through holes 123 in an upward direction.

The substrate support 122 is arranged in the lower chamber 102. In some examples, the substrate support 122 includes an electrostatic chuck (ESC), although other types of substrate supports can be used. A substrate 126 is arranged on an upper surface of the substrate support 122 during etching. In some examples, a temperature of the substrate 126 may be controlled. For instance, the substrate support 122 may be temperature controlled (heating and/or cooling) using one or more temperature control elements (TCEs) 139, such as resistive heaters (e.g., a heater plate 141), fluid channels 145 or other types of thermal control devices. The substrate support 122 may include a single temperature control zone or a plurality of temperature control zones that are individually controlled. In some examples, a temperature controller 143 and/or a coolant controller 147 may be used to control heating and cooling of the substrate support 122. Heating may be performed by the heater plate 141 and cooling may be performed by the cooling plate with the fluid channels 145. For example, the temperature controller 143 may communicate with one or more temperature sensors (not shown) that sense a temperature of the substrate support 122 or the substrate 126 and to the coolant controller 147 to control coolant flow through the channels 145. The controllers 143 and/or 147 may further include a source of fluid, a pump, control valves and a temperature sensor (all not shown).

In some examples, the gas distribution device 114 includes a showerhead (for example, a platen or a plate 128 having a plurality of spaced holes 129) arranged between the gas distribution device 121 and the substrate support 122. The plurality of spaced holes 129 extend from the upper surface of the plate 128 to the lower surface of the plate 128. The gas distribution device 114 may be used to redirect active strip species or etch species above the substrate 126.

Inductive coils 140 are arranged around an outer portion of the upper chamber wall 118. When energized, the inductive coils 140 create an electromagnetic field inside of the upper chamber wall 118. A gas injector 142 injects one or more gas mixtures from a gas delivery system 150-1 into the upper chamber 104. In some examples, the gas injector 142 injects the gas in one or more directions (such as center and side gas injection directions as shown in FIG. 1).

In some examples, the gas delivery system 150-1 includes one or more gas sources 152-1, 152-2, 152-N (collectively gas sources 152), one or more valves 154-1, 154-2, 154-N (collectively valves 154), one or more mass flow controllers (MFCs) 156-1, 156-2, 156-N (collectively mass flow controllers 156), and a mixing manifold 158, although other types of gas delivery systems may be used. A gas splitter (not shown) may be used to vary flow rates of a gas mixture. Another gas delivery system 150-2 may be used to supply a secondary gas (e.g., an etch gas, tuning gas, purge gas or other gas mixtures) to the secondary gas injectors 134. As can be appreciated, the gas delivery systems 150-1, 150-2 may be simplified in the case that the substrate processing system uses a single plasma gas and a single secondary gas.

In some examples, the gas injector 142 includes a center injection location that directs gas in a downward direction and one or more side injection locations that inject gas at an angle with respect to the downward direction. In some examples, the gas delivery system 150-1 delivers a first portion of the gas mixture at a first flow rate to the center injection location and a second portion of the gas mixture at a second flow rate to the side injection location(s) of the gas injector 142. In other examples, different gas mixtures are delivered by the gas injector 142. In some examples, the gas delivery system 150-2 delivers tuning gas to the secondary gas injectors 134 and/or to other locations in the processing chamber.

A plasma generator 170 may be used to generate RF power that is output to the inductive coils 140. Plasma 190 is generated in the upper chamber 104. In some examples, the plasma generator 170 includes an RF generator 172 and a matching network 174. The matching network 174 matches an impedance of the RF generator 172 to the impedance of the inductive coils 140. In some examples, the gas distribution device 114 is connected to a reference potential such as ground. A valve 178 and a pump 180 may be used to control pressure inside of the lower and upper chambers 102, 104 and to evacuate reactants therefrom.

A system controller 176 communicates with the gas delivery systems 150-1 and 150-2, the valve 178, the pump 180, and/or the plasma generator 170 to control flow of process gas, purge gas, tuning gas, RF plasma and chamber pressure. In some examples, plasma is sustained inside the upper chamber wall 118 by the inductive coils 140. One or more gas mixtures are introduced from a top portion of the chamber using the gas injector 142 (and/or the through holes 123) and plasma is confined within the upper chamber wall 118 using the gas distribution device 114.

Confining the plasma in the upper chamber wall 118 allows volume recombination of plasma species and effusing desired etchant species through the gas distribution device 114. In some examples, there is no RF bias applied to the substrate 126. As a result, there is no active sheath on the substrate 126 and ions are not hitting the substrate with any finite energy. Some of the ions will diffuse out of the plasma region through the gas distribution device 114. However, the amount of plasma that diffuses is an order of magnitude lower than the plasma located inside the upper chamber wall 118. Most of ions in the plasma are lost by volume recombination at high pressures. Surface recombination loss at the upper surface of the gas distribution device 114 also lowers ion density below the gas distribution device 114.

Referring now to FIGS. 1B and 1C, an asymmetric series RF coil arrangement includes first and second coils 140-1 and 140-2 and a first capacitor 194 and a second capacitor 196 that are arranged around an outer surface of the upper chamber 104. The first coil 140-1 is arranged around a lower portion of the outer surface of the upper chamber 104. One end of the first coil 140-1 is connected to one terminal of the first capacitor 194. The first capacitor C1 is inserted between the first and second coils to reduce the RF voltage on the coil. The first capacitor C1 is arranged adjacent to a mid-portion of the processing chamber. Another terminal of the first capacitor 194 is connected to one end of the second coil 140-2. The second coil 140-2 is arranged around an upper portion of the outer surface of the upper chamber 104. An opposite end of the second coil 140-2 is connected to the second capacitor 192 that is located above the processing chamber. The equivalent circuit is shown in FIG. 1C.

As can be appreciated, plasma density in locations near the first capacitor location is reduced due to distorted coil RF current at that location. As a result, the RF coupling to the plasma is locally reduced in the processing chamber, which causes a cold spot due to lower plasma density.

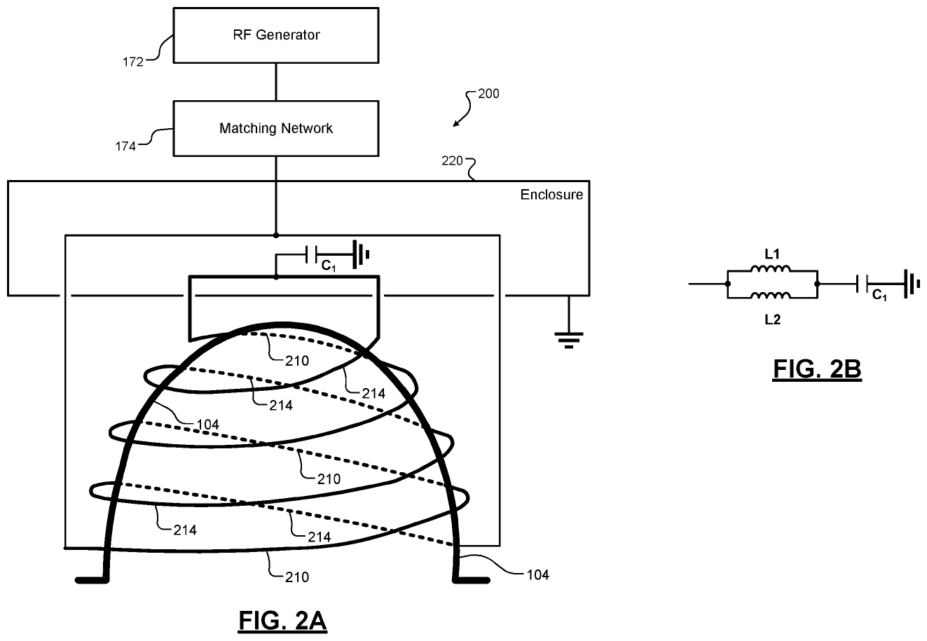

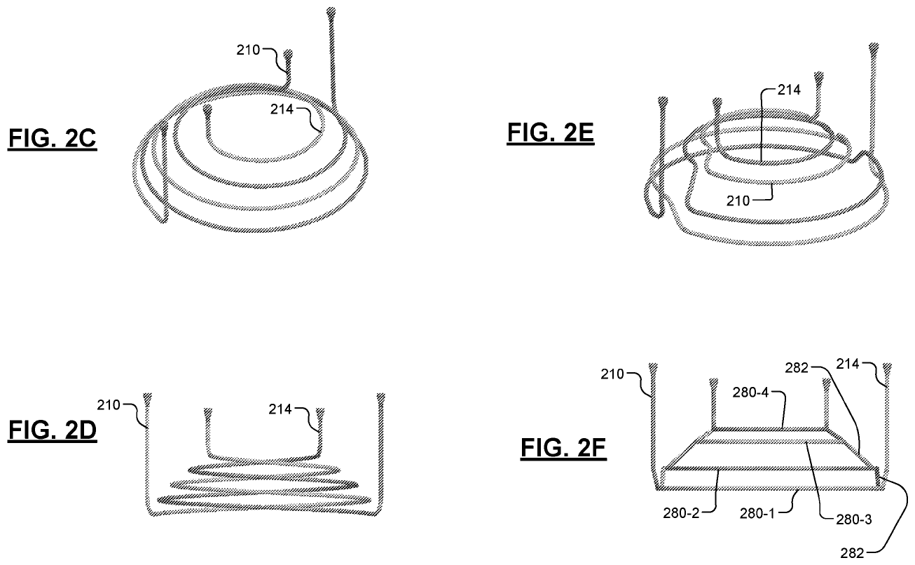

Referring now to FIGS. 2A to 2D, a substrate processing system 200 according to the present disclosure includes helical coils that are arranged at 180 degrees apart and interwound around the outer surface of the upper chamber 104 in a symmetric arrangement and connected in parallel. In FIGS. 2A and 2B, a first coil 210 and a second coil 214 have a helical shape and are interwound.

First ends of the first coil 210 and the second coil 214 are connected in parallel to an output of the matching network 174 and are located near a bottom of the processing chamber 104. Second ends of the first coil 210 and the second coil 214 are located near a top of the processing chamber 104 and are connected in parallel to a first capacitor C1 that is located inside the grounded enclosure and spaced from the outer surface of the upper chamber 104. While the first coil 210 and the second coil 214 are shown with two turns, additional turns can be used. In FIG. 2B, an equivalent circuit is shown.

One terminal of the first capacitor C1 is grounded and the first capacitor Ci is arranged in an enclosure 220. The enclosure 220 is made of a conducting material such as aluminum that is grounded to eliminate possible electromagnetic interference (EMI) to the plasma inside the processing chamber.

In this example, one of the first coil and the second coil is rotated 180° relative to the other one of the first coil and the second coil. The first coil and the second coil are connected in parallel in a side-by-side arrangement. Each coil has two turns with low inductance and low RF voltage.

The first capacitor (from FIGS. 1B and 1C) is removed to eliminate the corresponding cold spot. The capacitor C1 in FIG. 2A is isolated and shielded by ground plane and therefore has no effect on plasma uniformity. Connecting straps 226 and 228 are also isolated and shielded by the grounding plane and have no effect on plasma uniformity. In some examples, the connecting straps 226 and 228 are made of copper. The RF input and output are connected to the middle positions of the straps 226 and 228 to provide two symmetrical and identical coils.

The symmetric parallel RF source improves azimuthal plasma uniformity. In some examples, azimuthal uniformity of the symmetric parallel RF source is improved by greater than 50% relative to the asymmetric series RF source. Radial uniformity is the same or slightly improved and full wafer uniformity is also improved.

In FIGS. 2C and 2D, a perspective view and a plan view of an example of the first coil 210 and the second coil 214 are shown, respectively. The first coil 210 is rotated 180° relative to the second coil 214. The first coil 210 and the second coil 214 are identical. The first coil 210 and the second coil 214 are smoothly and gradually wound into a helical shape.

In FIGS. 2E and 2F, a perspective view and a plan view of another example of the first coil 210 and the second coil 214 are shown, respectively. The first coil 210 is rotated 180° relative to the second coil 214. The first coil 210 and the second coil 214 are identical. The first coil 210 and the second coil 214 transition between a plurality of different levels 280-1, 280-2, 280-3, 280-4 (as best seen in FIG. 2F) (collectively level portions 280). The first coil 210 and the second coil 214 are wound with a plurality of level portions and vertical transitions 282 between the level portions. The first coil 210 and the second coil 214 can have equal or non-equal distances from one level to an adjacent level.

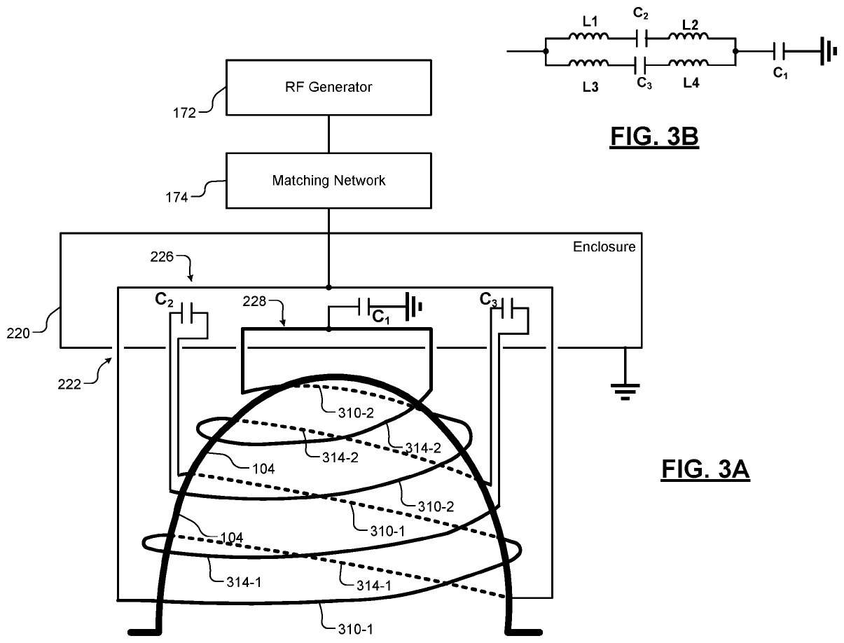

Referring now to FIGS. 3A to 3B, a substrate processing system according to the present disclosure includes first and second helical coils that are connected in parallel, interwound and arranged around the outer surface of the upper chamber 104. In FIGS. 3A and 3B, if a higher frequency such as 27.12 MHz is applied, or if it is needed to further reduce the RF voltage on the coils, a capacitor can be inserted at the middle position of each coil to decrease the RF voltage. the one or more coils include a first coil 310-1, a second coil 310-2, a third coil 314-1 and a fourth coil 314-2. A second capacitor C2 is arranged between the first coil 310-1 and the second coil 310-2. A third capacitor C3 is arranged between the third coil 314-1 and the fourth coil 314-2.

The pairs of coils (the first coil 310-1 and the second coil 310-2; and the third coil 314-1 and the fourth coil 314-2) have a helical shape and are interwound. First ends of the first coil 310-1 and the third coil 314-1 are connected in parallel to the matching network 174 and are located near a bottom of the upper chamber 104.

Second ends of the second coil 310-2 and the fourth coil 314-2 are located near a top of the processing chamber and are connected in parallel to the first capacitor C1 that is located spaced from the outer surface of the upper chamber 104. While the pairs of coils (the first coil 310-1 and the second coil 310-2; and the third coil 314-1 and the fourth coil 314-2) are shown with two turns, additional turns can be used. The first capacitor C1, the second capacitor C2, and the third capacitor C3 are arranged inside the enclosure 220. While two turns are shown and described above, the symmetric parallel RF source can include additional turns. Extended designs may have more than two turns for each coil and may operate at frequencies in a range from 300kHz to 30 MHz.

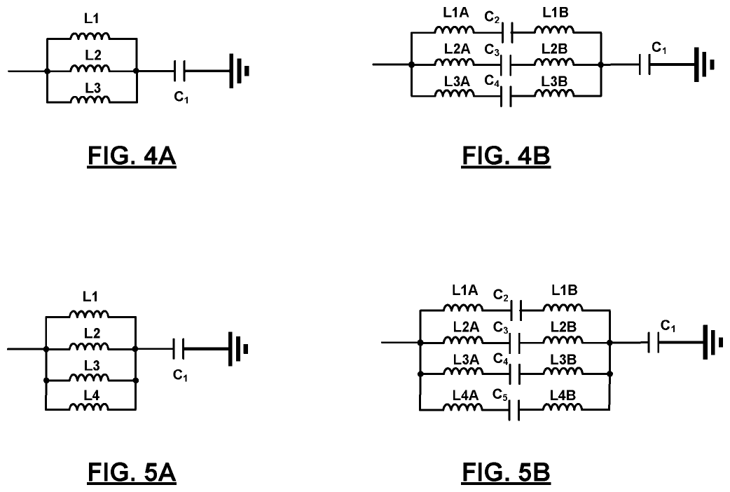

Referring now to FIGS. 4A to 5B, additional helical coils can be interwound and connected in parallel. For example, in FIGS. 4A and 4B, three coils L1, L2, and L3 or coil pairs L1A and L1B, L2A and L2B, and L3A and L3B (with middle capacitors C2, C3 and C4) can be used. Example, the coils are rotated by 360/N, where N is equal to the number of coils or coil pairs (when middle capacitors are used as in FIGS. 3A and 3B).

For example, in FIGS. 5A and 5B, four coils L1, L2, L3 and L4 or coil pairs L1A and L1B, L2A and L2B, L3A and L3B, and L4A and L4B (with intervening capacitors C2, C3, C4, and C5) can be used.

In FIGS. 4A to 5B, three or four identical coils or coil pairs are interwound and connected in parallel. The coils are placed uniformly (e.g. spaced at 360°/N) in an azimuthal direction. These designs improve uniformity of RF coupling to plasma in the azimuthal direction. Each coil includes two or more turns and can be used for frequencies in a range from 300kHz to 30 MHz. Middle capacitors can be added to further reduce RF voltage on the coils.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform, or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a processing chamber;
an RF generator configured to generate RF power;
a matching network connected to the RF generator; and
N helical coils connected to the matching network and including M turns, where N and M are integers greater than one,
wherein the N helical coils are interwound symmetrically around an outer surface of the processing chamber, and
wherein the N helical coils are connected in parallel to the matching network.

2. The substrate processing system of claim 1, wherein N and M are equal to two.

3. The substrate processing system of claim 1, wherein N is equal to 3.

4. The substrate processing system of claim 1, wherein N is equal to 4.

5. The substrate processing system of claim 1, wherein first ends of the N helical coils are connected to the matching network.

6. The substrate processing system of claim 5, wherein the first ends of the N helical coils are connected adjacent to a bottom portion of the processing chamber.

7. The substrate processing system of claim 1, further comprising a first capacitor, wherein second ends of the N helical coils are connected to a first terminal of the first capacitor.

8. The substrate processing system of claim 7, wherein the second ends of the N helical coils are connected adjacent to a top portion of the processing chamber.

9. The substrate processing system of claim 7, further comprising a ground plane arranged between the first capacitor and the N helical coils.

10. The substrate processing system of claim 7, further comprising an enclosure surrounding the first capacitor, wherein the enclosure is made of a conducting material that is grounded.

11. The substrate processing system of claim 1, wherein the N helical coils are rotationally offset by 360/N degrees.

12. The substrate processing system of claim 11, further comprising N capacitors that are connected between middle portions of the N helical coils.

13. The substrate processing system of claim 11, wherein N is equal to 2.

14. The substrate processing system of claim 11, wherein N is equal to 3.

15. The substrate processing system of claim 11, wherein N is equal to 4.

16. The substrate processing system of claim 12, further comprising an enclosure surrounding a first capacitor and the N capacitors, wherein the enclosure is made of a conducting material that is grounded.

17. The substrate processing system of claim 1, wherein the processing chamber has one of a dome shape and a bell jar shape.

18. The substrate processing system of claim 1, wherein the N helical coils are smoothly and gradually wound into a helical shape.

19. The substrate processing system of claim 1, wherein the N helical coils are wound into a helical shape with a plurality of levels and transitions between the plurality of levels.

20. The substrate processing system of claim 19, wherein the plurality of levels is evenly spaced in a vertical direction.

21. The substrate processing system of claim 19, wherein a first vertical spacing between a first pair of the plurality of levels is different than a second vertical spacing between a second pair of the plurality of levels.
